(19) United States
(12) Patent Application Publication
(10) Pub. No.: US 2005/0040030 A1
(43) Pub. Date: Feb. 24, 2005

(54) Method of treating sputtering target to reduce burn-in time and sputtering target thereof and apparatus thereof

(76) Inventor: Peter H. McDonald, Blauvelt, NY (US)

Correspondence Address: PRAXAIR, INC.;LAW DEPARTMENT - MI 557, 39 Old Ridgebury Road, Danbury, CT, 06810-5113, US

(21) Appl. No.: 10/643,986

(22) Filed: Aug. 20, 2003

(51) Int. Cl. C23C 14/32

(52) U.S. Cl. 204/192.12; 204/298.02

(57) ABSTRACT

A method for dry treating a sputtering target using a sputtering ion plasma at low power to effectively reduce burn-in time of the target; the target so produced; and apparatus used for the target treatment.

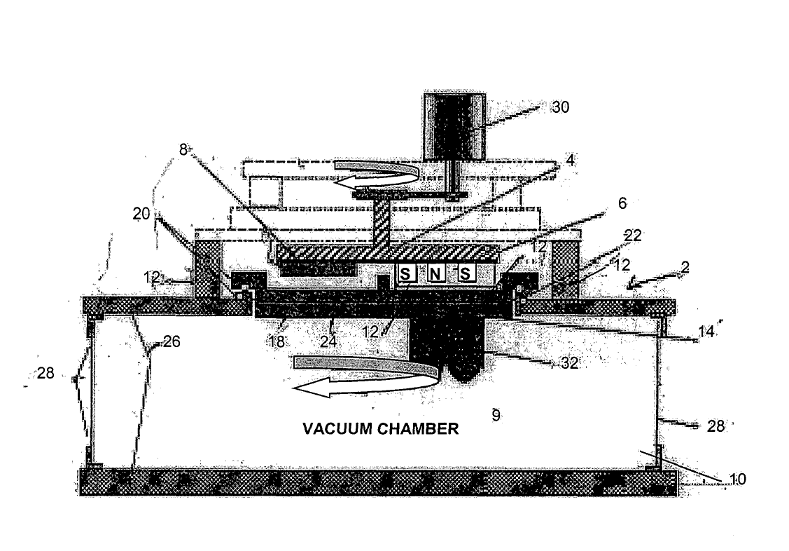

### FIELD OF THE INVENTION

This invention relates to a method of dry treating a sputtering target to achieve an enhanced finish on the surface that effectively reduces burn-in time of the target and the target and opposition for the treating thereof.

### BACKGROUND OF THE INVENTION

In the manufacture of sputtering targets used for many applications, such as the semi-conductor industry, it is desirable to produce a target with a sputter surface that will provide film uniformity during sputtering onto a wafer such as a semi-conductor wafer. The typical manufacturing processes for sputter targets result in targets with surface defects. Additionally, the materials comprising the sputter targets, such as titanium, aluminum, tantalum, nickel, chromium, cobalt, copper and alloys thereof, have inherently problematic characteristics (i.e., uniformity and burn-in time requirements) that are a result of the machining process. These inherent defects and characteristics generally have an adverse effect on the end user of the sputter target product.

Among the undesirable effects of sputter target manufacture is the lengthy burn-in time for a new sputter target at the customer site. Typically, sputter targets, such as titanium targets, exhibit poor film uniformity during the early stages of target use. As a result, a burn-in cycle, which eliminates the surface defects of the target, must be performed at generally 30 kWh before the target surface will produce high quality thin film wafers. It is not uncommon for a standard target to go through about 30 or more wafers during the burn-in cycle before it produces high quality wafers, which is equivalent to about 12 kWh. Deposition without this burn-in cycle would result in a relatively high reject rate of poor quality wafers. Thus, a burn-in cycle is generally required to achieve a sputter surface that will provide the desired film uniformity, thus requiring a customer to waste valuable processing time and materials. By way of example, for titanium targets, a Rₛ uniformity of less than 1.6 is desirable for most applications. Rₛ uniformity is 49 points with 3 mm edge exclusion on a 300 mm wafer. As produced, targets generally have a Rₛ greater than 1.6%.

Various attempts have been made to reduce, eliminate or control the inherently undesirable characteristics resulting from the manufacturing process for sputter targets. For example, grinding, lapping, fine machining, lathes, and hand polishing have been used to remove the surface material of the target. These methods of material removal are time consuming, labor intensive, costly, dirty and provide inconsistent results. While polishing to a mirror finish may provide a good surface finish, it requires extensive preparation and time, usually 24 hours, which is unsuitable for a production environment, and there is no guarantee the same result may be obtained consistently for subsequent targets. An acceptable method for enhancing the surface of a target material as disclosed in U.S. Pat. No. 6,309,556 involves chemically etching the surface of the sputter target by immersing the surface one or more times in an etching solution, with intermediate rinsing steps.

The burn-in processing is a non-value step as part of the sputtering process. This non-value step impacts the entire manufacturing process and can contribute to increased cost of production. To illustrate, sputtering systems are very expensive and downtime on this equipment is expensive. Burn-in of a new target generally takes at least one hour that cannot be used for production. Reducing burn-in time will result in significant savings and reduction of cost of product. In view of the disadvantages associated with the need to burn-in a target, i.e., increased manufacturing time and possible adverse effects on the sputtering operation and the manufactured product yield, a need has developed to improve the sputtering target processing sequence to reduce the burn-time and improve the overall manufacturing process and process yield.

In response to this need, the present invention overcomes the disadvantages noted above by providing a method which dry treats a target surface with a sputtering ion plasma using a low kW operated magnetron sputtering apparatus.

### SUMMARY OF THE INVENTION

A method of dry treating a target surface prior to using the target for sputtering comprising:
a) preparing a target assembly and securing said target assembly in a vacuum chamber of a magnetron sputtering apparatus, said target assembly having a target surface with a specific morphology;
b) energizing the magnetic component of the magnetron sputtering apparatus to produce a surface dry treatment of a sputtering ion plasma on an exposed surface of the target assembly so that the Rₛ uniformity of the surface of a substrate, such as a wafer, in a sputtering apparatus can be reduced by at least 10% thus illustrating the reduction of the burn-in period of the target; and
c) removing the treated target assembly from the apparatus.

As used herein, the term “target assembly” includes sputtering targets which are either one piece or which include a supporting target backplate. Preferably, the magnetron apparatus is rotatable and the magnetic component of the magnetron sputtering apparatus is disposed on less than a 180° arc measured at the axis of rotation of the apparatus so as to produce a rotatable sputtering ion plasma on the surface of the target. Substrate to be coated, wafer, generally have a surface with a Rₛ uniformity in excess of 1.6%. Target assemblies having a Rₛ uniformity of more that 1.6% are generally rejected outright by customers. Wafers just below Rₛ uniformity of 1.6% generally requires a long burn-in period.

The novel magnetron sputtering apparatus of this invention can be operated between about 0.2 kW and 4 kW, more preferably between about 0.2 kW and about 0.9 kW and most preferably between about 0.2 kW and about 0.4 kW for a period of time between about 4 and about 30 minutes, more preferably between about 6 and about 15 minutes, and most preferably between about 8 and about 12 minutes.

The magnetron sputtering apparatus should treat the surface of the target assembly in an inert environment such as argon. The process conditions recited above will effectively treat the surface of the target assembly so that the Rₛ uniformity of a wafer can be reduced by at least 10% or a Rₛ uniformity percent of a wafer can be reduced to less than about 1.5%, preferably less than about 1.20% and most preferably less than about 1.10%.

Suitable sputter target can be made of a material selected from the group comprising titanium, aluminum, copper, molybdenum, cobalt, chromium, ruthenium, rhodium, palladium, silver, osmium, iridium, platinum, gold, tungsten, silicon, tantalum, vanadium, nickel, iron, manganese, germanium, or alloys thereof.

### BRIEF DESCRIPTION OF THE DRAWING

The sole drawing is a cross-section of a magnetron sputtering apparatus containing a target assembly.

### DETAILED DESCRIPTION

The present invention relates to the treatment of the morphology of a sputtering target surface, its conditioning and preservation during shipment and storage until installation into a commercial sputter apparatus. The invention is intended to minimize the sputtering target's initial burn-in stage as well as reducing the burn-in time. These objectives are met by a surface treatment of the target.

Generally, sputtering targets are manufactured by conventional processing steps such as selecting a target alloy material, melting it and casting it into an ingot. The ingot is then worked, either by hot-working, cold-working or a combination thereof and heat treated to form the final manufactured target. Other conventional steps may include machining, bonding, if required, final machining and cleaning before the target is ready for use in sputtering.

According to the invention, the conventionally produced target is subjected to a surface treatment step. The purpose of the surface treatment step is to produce a surface similar to one that would be produced by a burn-in sequence but without the actual burning-in. The inventive surface treatment step is to reduce burn-in time. Thus, if the target surface can be made to resemble a target that has been subjected to a burn-in process, less burn-in time is required, thus improving the economics of the overall device manufacturing process.

This surface treatment can be carried out using the magnetron sputtering apparatus shown in the sole drawing in which the apparatus 2 comprises a rotating disk 4 containing a magnet assembly 6 balanced with a countervergent 8. Preferably the magnet component 9 of the magnet assembly 6 is a FeNdB. The rotating disk 4 is secured to the vacuum chamber 10 by electrical insulating blocks 12. Disposed beneath the rotating disk assembly 4-6-8 is a target assembly 14 composed of backplate 16, secured to a target component 18 by viton ‘O’ rings 20 and teflon insulator ring 22. The target component 18 has its surface 24 facing into the vacuum chamber 10. The vacuum chamber 10 comprises support plates 26 with a side viton vacuum seal 28. A drive motor 30 drives the rotating disk 4 and thus rotates magnet assembly 6. When magnet assembly 6 is energized by a power source (not shown), a rotating sputtering plasma 32 is produced in an inert atmosphere such as argon that can treat the surface 24 of the target component 18. By selecting a desired time and power, as discussed below, to energize the magnet assembly 6, a sputtering plasma 32 will rotate and treat the surface 24 in a novel pattern to provide a uniform, dry surface treatment with minimal material removed. The novel treatment can effectively reduce the Rₛ uniformity of the surface of a wafer by at least 10% and less than Rₛ uniformity 1.6%.

### EXAMPLE

Using the magnetron sputtering apparatus as described in the drawing, the magnet assembled was energized with 0.3 kW power for 8 minutes at 2.5 micron argon. Rₛ uniformity of a wafer surface was determined for several wafers. After the Rₛ uniformity of a wafer surface was determined, the target surface was machined by 0.05 mm to simulate a new target surface. The target surface was then treated by the sputtering plasma at low power as shown below. The results are shown in the following table.

| | | Wafer/Rₛ Uniformity |
|---|---|---|
| Sample | Treatment | (1 Sigma %) |
| 1 | as above | 1.20% |
| 1 | 1 kW at 8 minutes | 1.04% |
| 2 | as above | 1.46% |
| 2 | 1 kW at 8 minutes | 1.28% |
| 3 | as above | 1.54% |
| 4 | as above | 1.33% |

“As above” means 0.3 kW, 8 minutes, 2.5 microns argon.

Normally, the process condition for normal burn-in is an incremental step process to a maximum power of at least 8 kw for at least 3 hours. Using the novel treatment of this invention, the burn-in time necessary to qualify the target for use in production is reduced. The novel treatment involves minimal surface removal thereby increasing the number of usable wafers for a given sputtering target. The advantages the invention are:
1) it does not contaminate target surface with water or any other chemical agent,
2) it is inexpensive to build and operate,
3) it treats the primary sputter erosion zone of a suptter target,
4) it does not use any toxic materials,
5) it does not require additional clearing of target before packaging, and
6) it can be used to treat final sputter target assemblies.

Once the surface of the target assembly is treated, at least the surface treated portion of the target is then placed in an enclosure sized to protect the surface treated portion. The enclosure prevents contact between the surface treated portion of the target and any subsequently applied packaging material or enclosure surrounding the target and the enclosure. The surface treatment combined with the enclosure substantially reduces contamination on the target surface resulting in reduced arcing, organic radicals and carbon levels during burn-in. Consequently, the burn-in time reduction is maintained. The enclosure and target assembly can then be further enclosed in a plastic enclosure such as a double-plastic bag for clean room utilization. The enclosure can be evacuated for shipping and storing purposes. Preferably, the initial enclosure is metallic because the metallic can prevent contact or exposure between a plastic bag and the surface of the target. Plastic or polymeric materials tend to contaminate the target surface by providing a source of organic material which would be detrimental if present in the sputtering or burn-in process. A metallic enclosure eliminates contact between the target and any plastic and any source of organic radicals and carbon generated during sputtering and/or burn-in. It should be understood that any metal having sufficient strength can be used as the metal enclosure, e.g., ferrous or non-ferrous metals, either in laminate, coated, composite or other known forms. The enclosure can comprise a non-metallic core, e.g., plastic, a composite or the like, and a metal coating thereon. The metal coating can cover the entire non-metallic core or just the portion adjacent the surface treated target portion. A metallic enclosure is deemed to encompass any enclosure having at least a metal portion protecting and/or isolating the surface treated target portion.

Without departing from the spirit or scope of the present invention, the invention in its broader aspects is therefore not limited to the specific details and illustrative example shown and described. Accordingly, departures may be made from such details without departing from the spirit or scope of Applicants' general inventive concept. Therefore, Applicants desire to be limited only by the scope of the following claims and equivalents thereof.

1. A method of dry treating a target surface prior to using the target for sputtering comprising:
a) preparing a target assembly and securing said target assembly in a vacuum chamber of a magnetron sputtering apparatus;
b) energizing the magnetic component of the magnetron sputtering apparatus with a power between about 0.2 kW and about 4 kW for a period of time between about 4 and about 30 minutes to produce a surface dry treatment of a sputtering ion plasma on an exposed surface of the target to effectively reduce inherently undesirable impurities on the surface; and
c) removing the treated target assembly from the magnetron sputtering apparatus.

2. The method of claim 1 wherein the magnetron sputtering apparatus is rotatable and the magnetic component of the magnetron sputtering apparatus is disposed on less than a 180° arc measured at the axis of rotation of the apparatus so as to produce a rotatable sputtering ion plasma on the surface of the target.

3. The method of claim 1 wherein the target surface is treated for a time period between about 8 and about 10 minutes and a power of between about 0.2 kW and about 0.4 kW.

4. The method of claim 4 wherein the target surface is treated as an inert atmosphere.

5. The method of claim 6 where the inert atmosphere is argon.

6. The method of claim 1 wherein after removing the target assembly from the magnetron sputtering apparatus in step c), at least the surface treated portion of the target assembly is placed in an enclosure to protect it during storage and shipment.

7. The method of claim 8 wherein the enclosure is metallic and the metallic enclosure containing the target assembly is further placed into a different enclosure.

8. The method of claim 1 wherein the target material selected from the group comprising titanium, aluminum, copper, molybdenum, cobalt, chromium, ruthenium, rhodium, palladium, silver, osmium, iridium, platinum, gold, tungsten, silicon, tantalum, vanadium, nickel, iron, manganese, germanium, or alloys thereof.

9. The method of claim 2 wherein the magnetic component is FeNdB.

10. The method of claim 2 wherein the following step is added:
d) assembling the treated target assembly into a sputtering apparatus to coat the substrate and then sputtering the target and the burn-in time required is reduced by at least 10% using the treated target of step b) compared to an untreated target.

11. The method of claim 10 wherein the target surface is treated for a time period between about 8 and about 10 minutes and a power of between about 0.2 kW and about 0.4 kW.

12. The method of claim 11 wherein the target material selected from the group comprising titanium, aluminum, copper, molybdenum, cobalt, chromium, ruthenium, rhodium, palladium, silver, osmium, iridium, platinum, gold, tungsten, silicon, tantalum, vanadium, nickel, iron, manganese, germanium, or alloys thereof.

13. A treated target assembly made by the method of claim 2.

14. The treated target assembly of claim 13 wherein the target surface is treated for a time period between about 8 and about 10 minutes and a power of between about 0.2 kW and about 0.4 kW.

15. The treated target assembly of claim 10 wherein the target material selected from the group comprising titanium, aluminum, copper, molybdenum, cobalt, chromium, ruthenium, rhodium, palladium, silver, osmium, iridium, platinum, gold, tungsten, silicon, tantalum, vanadium, nickel, iron, manganese, germanium, or alloys thereof.

16. A magnetron sputtering apparatus comprising a vacuum chamber with a surface defining an opening adapted for securing a removable target assembly; support structure surrounding the opening of the vacuum chamber and spaced outside of securing means for the removable target, a rotating magnet assembly secured to the support structure and disposed over the opening and adapted to be spaced apart from the removable target assembly, motor means for rotating the magnet assembly, and power means for energizing the magnet assembly.

17. The magnetron sputtering apparatus of claim 16 wherein the magnetic component of the magnetron sputtering apparatus is disposed on less than a 180° arc measured at the axis of rotation of the apparatus so as to produce a rotatable sputtering ion plasma on the surface of the target.

18. The magnetron sputtering apparatus of claim 17 wherein the magnet assembly contains a FeNdB magnet component.

19. The magnetron sputtering apparatus of claim 17 wherein the vacuum chamber comprising a bottom support plate, an upper support plate defining the opening and viton vacuum seal side enclosure.

20. The magnetron sputtering apparatus of claim 19 wherein a removable target assembly is secured into the opening in the upper support plate.
